(19) United States
(12) Patent Application Publication
(10) Pub. No.: US 2020/0194234 A1
(43) Pub. Date: Jun. 18, 2020

(54) VACUUM CHAMBER OPENING SYSTEM

(71) Applicant: Lam Research Corporation, Fremont, CA (US)

(72) Inventors: Leonid BELAU, Pleasanton, CA (US); Eric HUDSON, Berkeley, CA (US); John HOLLAND, San Jose, CA (US)

(21) Appl. No.: 16/222,178

(22) Filed: Dec. 17, 2018

(51) Int. Cl. H01J 37/32; H01L 21/67; H01L 21/687; H01L 21/3065

(52) U.S. Cl. CPC H01J 37/32513; H01J 37/32743; H01J 37/32788; H01J 37/3244; H01L 21/67069; H01J 2237/166; H01L 21/3065; H01J 37/32715; H01J 37/32082; H01J 37/32834; H01L 21/68707

(57) ABSTRACT

An apparatus for processing substrates is provided. A chamber comprises a chamber top and a chamber bottom, wherein the chamber bottom is detachably connected to the chamber top. At least one substrate support supports at least one substrate in the chamber. A substrate port allows a substrate to move into or out of the chamber. A seal creates a vacuum seal when the chamber top is on the chamber bottom. A manipulation system for manipulating an interior of the chamber when the chamber top is spaced apart from the chamber bottom comprises 1) a sealing wall for creating a seal between the chamber top and chamber bottom when the chamber top is spaced apart from the chamber bottom and 2) a manipulation port in the sealing wall, wherein the manipulation port allows a mechanical force to be provided through the sealing wall inside the chamber.

### BACKGROUND

The disclosure relates to an apparatus for forming semiconductor devices on a semiconductor wafer. More specifically, maintaining systems for forming semiconductor devices.

In forming semiconductor devices, semiconductor device systems may use hazardous gases. Such systems are purged before the systems are opened.

### SUMMARY

To achieve the foregoing and in accordance with the purpose of the present disclosure, an apparatus for processing substrates is provided. A chamber comprises a chamber top and a chamber bottom, wherein the chamber bottom is detachably connected to the chamber top. At least one substrate support supports at least one substrate in the chamber. A substrate port allows a substrate to move into or out of the chamber. A seal creates a vacuum seal when the chamber top is on the chamber bottom. A manipulation system for manipulating an interior of the chamber when the chamber top is spaced apart from the chamber bottom comprises a sealing wall for creating a seal between the chamber top and chamber bottom when the chamber top is spaced apart from the chamber bottom and a manipulation port in the sealing wall, wherein the manipulation port allows a mechanical force to be provided through the sealing wall inside the chamber.

In another manifestation, a vacuum chamber opening system for a chamber is provided, wherein the chamber comprises a chamber top and a chamber bottom, wherein the vacuum chamber opening system seals the chamber as the chamber top is moved to be spaced apart from the chamber bottom. The vacuum opening system comprises a sealing wall for creating a seal between the chamber top and chamber bottom as the chamber top is moved to be spaced apart from the chamber bottom and a manipulation port in the sealing wall, wherein the manipulation port allows mechanical force to be provided through the sealing wall inside the chamber, when the chamber top is spaced apart from the chamber bottom.

These and other features of the present disclosure will be described in more details below in the detailed description and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1A is a schematic cross-sectional side view of a plasma processing chamber that may be used in an embodiment.

FIG. 1B is a top view of the plasma processing chamber shown in FIG. 1A

FIG. 1C is an enlarged view of a section of the plasma processing chamber shown in FIG. 1A

FIG. 2 is a schematic view of the plasma processing chamber after a chamber top has been separated from a chamber bottom.

FIG. 3 is a schematic view of a robotic arm used in an embodiment.

### DETAILED DESCRIPTION OF THE EMBODIMENTS

The present disclosure will now be described in detail with reference to a few exemplary embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well-known process steps and/or structures have not been described in detail in order to not unnecessarily obscure the present disclosure.

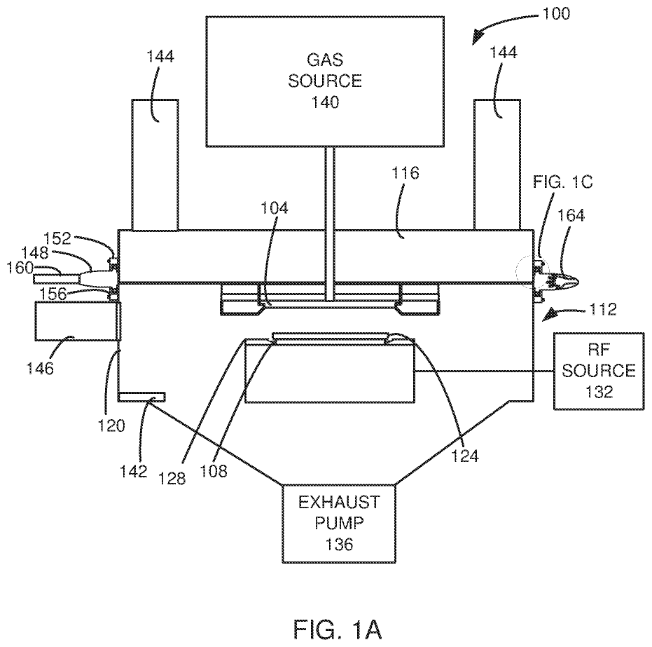

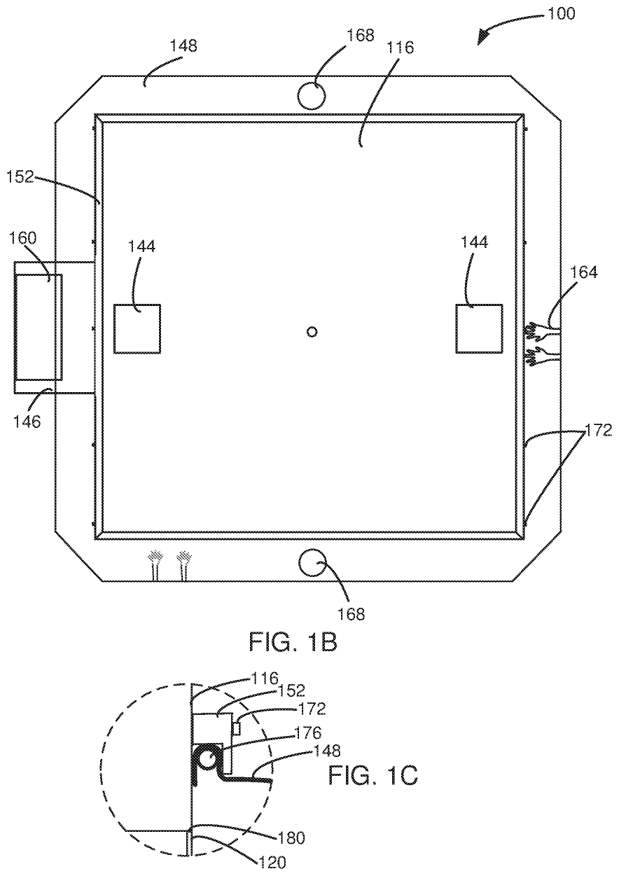

In an exemplary embodiment, FIG. 1A is a schematic cross-sectional side view of a plasma processing chamber that may be used in an embodiment. In one or more embodiments, a plasma processing chamber 100 comprises a gas distribution plate 104 providing a gas inlet and an electrostatic chuck (ESC) 108, within a chamber 112. The chamber 112 comprises a chamber top 116 and a chamber bottom 120 with a vacuum seal between the chamber top 116 and chamber bottom 120. Within the chamber 112, a substrate 124 is positioned over the ESC 108, so that the ESC 108 provides a substrate support. An edge ring 128 surrounds the ESC 108. A radio frequency (RF) source 132 provides RF power to a lower electrode, which in this embodiment is the ESC 108. In an exemplary embodiment, 400 kHz and 60 MHz power sources make up the RF source 132. In this embodiment, an upper electrode, the distribution plate 104, is grounded. In this embodiment, one generator is provided for each frequency. Other arrangements of RF sources and electrodes may be used in other embodiments. An exhaust pump 136 is in fluid connection with the chamber bottom 120. A gas source 140 is in fluid contact with the distribution plate 104. A pressure sensor 142 is placed to measure pressure in the chamber 112. An actuator 144 is connected to the chamber top 116 in order to allow the raising of the chamber top 116. A substrate port 146 is connected to the chamber bottom 120 and provides access for adding and removing the substrate 124 to and from the chamber 112. An example of such a chamber is the Flex® etch system manufactured by Lam Research Corporation of Fremont, Calif. The plasma processing chamber 100 can be a CCP (capacitively coupled plasma) reactor or an ICP (inductively coupled plasma) reactor.

A vacuum chamber opening system is connected between the chamber top 116 and the chamber bottom 120. The vacuum chamber opening system is designed to open the chamber for inspection without exposure to a hazardous environment. The vacuum chamber open system comprises a sealing wall 148 connected to a top mounting system 152 for mounting the sealing wall 148 to the chamber top 116 and a bottom mounting system 156 for mounting the sealing wall 148 to the chamber bottom 120. A load lock chamber 160 is connected to the sealing wall 148. The load lock chamber 160 is a chamber between the interior of the chamber 112 and the atmosphere with gas-tight doors between the load lock chamber 160 and the interior of the chamber 112 and between the atmosphere and the load lock chamber 160. A pump may also be connected to the load lock chamber 160. The load lock chamber 160 allows an object to pass into or out of the chamber 112 through the gas-tight doors. The load lock chamber 160 may minimize gases that pass from the chamber 112 to atmosphere or from atmosphere to the chamber 112. During a transfer of an object, the gas-tight doors stop the flow of gas from the chamber 112 to the load lock chamber 160 and the flow of gas from the atmosphere to the load lock chamber 160, when an object is in the load lock chamber 160. The load lock chamber 160 may be pumped down to remove some of the gas in the load lock chamber 160. After the load lock chamber 160 is sufficiently pumped down, one of the gas-tight doors is opened to allow the object to be removed out of the load lock chamber 160. Gloves 164 are also mounted in the sealing wall 148.

FIG. 1B is a top view of the plasma processing chamber 100. The chamber top 116 is surrounded by the sealing wall 148. The sealing wall 148 is secured to the chamber top 116 by the top mounting system 152. Optical ports 168 are mounted in the sealing wall 148. The optical ports 168 allow light to pass through the optical ports 168 for optical detection and analysis of the interior of the plasma processing chamber 100. The sealing wall 148 may be transparent in order to allow viewing of the interior of the plasma processing chamber 100. However, the optical ports 168 may provide improved transmission of a light beam through the sealing wall 148 in order to improve optical measurements or detection.

FIG. 1C is an enlarged view of a section of the plasma processing chamber 100 shown in FIG. 1A. The top mounting system 152 is a bracket attached to the chamber top 116 by a plurality of bolts 172. The top mounting system 152 holds part of the sealing wall 148 against a top O-ring 176. In addition, a chamber O-ring 180 is between the chamber top 116 and the chamber bottom 120 to create a vacuum seal between the chamber top 116 and the chamber bottom 120. The bolts 172 allow the vacuum chamber opening system to be removable. A removable vacuum chamber opening system allows the plasma processing chamber 100 to be used without the vacuum chamber opening system. When access to the interior of the plasma processing chamber 100 is needed, the vacuum chamber opening system may be mounted on the plasma processing chamber 100, and then the plasma processing chamber 100 may be opened for observation and manipulation.

In operation, the substrate 124 may pass into the chamber 112 through the substrate port 146. The gas source 140 may provide a process gas, such as an etch gas, into the chamber 112. The RF source 132 provides RF power to form the process gas into a plasma. The RF source 132 may also provide a bias to accelerate ions to the substrate 124. The plasma may be used to perform a process on the substrate. Such processes may be one or more of etching, stripping, or depositing. After the substrate 124 is processed, the substrate 124 may be removed from the chamber 112 through the substrate port 146. After one or more substrates 124 have been processed, the chamber 112 may be opened to inspect the chamber 112, clean the chamber 112, service internal chamber parts, replace internal chamber parts, or test the chamber 112.

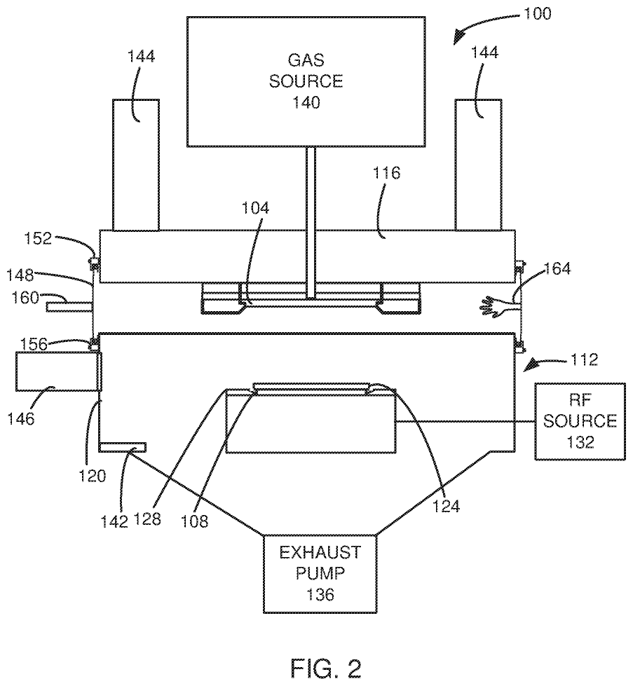

FIG. 2 is a schematic view of the etch reactor after the chamber top 116 has been separated from the chamber bottom 120. In this example, the actuator 144 is used to raise the chamber top 116. Separating the chamber top 116 from the chamber bottom, causes the sealing wall 148 to unfold in order to remain extended between the chamber top 116 and the chamber bottom 120. The sealing wall 148 maintains a seal between the chamber top 116 and chamber bottom 120, as the chamber top 116 is separated from the chamber bottom 120 in order to prevent hazardous gas exposure. The ability of the sealing wall 148 to fold and unfold allows the sealing wall 148 to maintain a seal as the chamber top 116 is moved from being on the chamber bottom 120 to being spaced apart from the chamber bottom 120. The load lock chamber 160 allows test coupons, inspection materials, cleaning materials, internal chamber parts, or other items to be placed within or removed from the chamber 112 without venting hazardous gas. In addition, the gloves 164 form a glove box with the sealing wall 148. The gloves 164 may be used to manipulate items in the chamber 112, such as moving test coupons or cleaning or inspecting the chamber 112 or removing internal parts or installing internal parts. Multiple pairs of gloves may be placed at different locations around the sealing wall 148. The gloves 164 are used as manipulation ports. An optical light beam may pass through the optical ports 168 for inspecting the chamber 112. After testing, inspection, cleaning, or other processes are completed, the chamber top 116 is lowered until the chamber top 116 rests on the chamber bottom 120 and a seal between the chamber top 116 and chamber bottom 120 is established.

Without the vacuum chamber opening system, the chamber 112 may need to be decontaminated before opening the chamber 112. The processing of the substrate 124 frequently requires the use of hazardous chemicals. As a result, chamber parts become contaminated. A general procedure for chamber decontamination requires long pumping and purging (P/P) of the chamber 112 with inert gases (typically nitrogen or argon). In some cases, more than 6 hours are required for venting the chamber 112 to atmosphere prior to a safe open of the chamber 112. It is common to introduce water vapor inside the vacuum chamber during the P/P cycles. This is to enhance chamber decontamination by enabling chemical reaction between chemical residues and water. Resulting byproducts are frequently volatile and could be pumped away. However, in some cases, byproducts are not volatile and could not be safely removed. One example is low volatile fluorocarbon byproducts. Liquid HF (hydrofluoric) acid is a common reaction product that may accumulate on chamber parts. Besides being a health hazard, HF causes significant damage to internal chamber parts (especially ceramic and metal parts). Therefore, without the vacuuming opening system, long purge times are required before a chamber 112 can be opened for examination. The long purge times may increase damage to the internal chamber parts.

In order to improve vacuum chamber internal part design, engineers are required to have frequent access to chamber parts. This is required to study polymer accumulation and composition during silicon (Si) wafer etch processing. In addition, contaminated chamber parts inspection is required to optimize automatic chamber cleaning sequences. However, the current vacuum chamber open procedure does not allow safe access to any internal chamber parts. Moreover, after complete decontamination cycles, reactive polymer resides undergo a chemical reaction with water vapor (introduced during the P/P cycles). As a result, it is not possible to have an accurate analysis of polymer build up. The vacuum chamber opening system allows inspection of polymer accumulation without purging so that the polymer accumulation is not altered during the purging.

In this embodiment, the sealing wall 148 is a single layer of a flexible material, such as clear plastic. The sealing wall 148 must be resistant to damage from chemicals that the sealing wall 148 is exposed to. For example, preferably the sealing wall is of material that is not damaged by exposure to a halogen, such as hydrogen fluoride (HF) or hydrogen bromide (HBr) or sulfur oxides. In other embodiments, the sealing wall 148 may have two or more layers to provide additional sealing safety. In other embodiments, the sealing wall 148 may be more rigid and hinged, like bellows. The sealing wall 148 must be able to extend and between the chamber top 116 and the chamber bottom 120, as the chamber top 116 and the chamber bottom 120 are moved apart and then back together.

When the chamber needs to be opened, the pressure inside the chamber 112 is increased to be within 10% of the atmospheric pressure outside of the chamber 112. The pressure inside the chamber 112 being within 10% of the atmospheric pressure outside of the chamber 112 is defined as the difference between the atmospheric pressure outside the chamber 112 and the pressure inside the chamber 112 is no more than 10% of the atmospheric pressure outside the chamber 112. Preferably, the pressure inside the chamber 112 is increased to be within 1% of the atmospheric pressure outside the chamber 112. A small difference in pressure means that the sealing wall 148 and the top mounting system 152 and the bottom mounting system 156 need to be only strong enough to withstand and create a barrier for a small difference in pressure. In some embodiments, the pressure in the chamber 112 is greater than but within 1% of the pressure outside the chamber 112. An advantage in these embodiments is that the sealing wall 148 would bow outward. When the chamber top 116 is placed on the chamber bottom 120 the sealing wall 148 bowing outward would not be pinched between the chamber top 116 and the chamber bottom 120. Another advantage is that if there is a leak in the sealing wall 148, it would be easier to detect the leak. In other embodiments, the pressure in the chamber 112 is less than but within 1% of the pressure outside the chamber 112. An advantage in these embodiments is that if there was a leak in the sealing wall a net gas flow would be into the chamber 112 so that hazardous gas would not leak out of the chamber 112.

In various embodiments, the vacuum chamber opening system is detachably connected between the chamber top 116 and the chamber bottom 120. The vacuum chamber opening system may be attached to the chamber 112 only when the chamber 112 is to be opened for servicing. The vacuum chamber opening system may then be removed when not needed. In addition, a detachable vacuum chamber opening system would be easier to repair if any leaks are found. In other embodiments, the vacuum chamber opening system may be permanently connected to the chamber 112.

In other embodiments, the chamber 112 may be a deposition chamber or a stripping chamber or another substrate processing chamber. In various embodiments, the gas source 140 may be used to provide a gas to produce a set pressure. The gas source 140 may provide an inert gas such as nitrogen (N₂) or argon (Ar) to maintain the set pressure. The pressure sensor 142 measures the pressure in the chamber 112. The exhaust pump 136 exhausts gas in the chamber in order to maintain the set pressure range. A feedback loop between the exhaust pump 136, gas source 140, and pressure sensor 142 may be used to provide a pressure system to detect a leak.

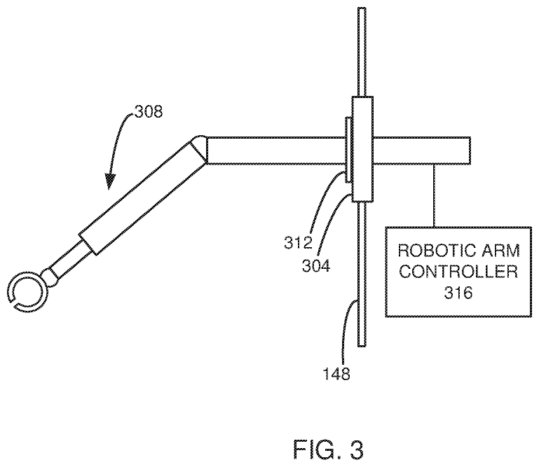

In some embodiments, robotic arm ports may replace or be provided in addition to gloves. Such robotic arm ports and gloves are manipulation ports that allow access for providing a manipulation force inside the chamber 112. FIG. 3 is a schematic illustration of a manipulation system with a sealing wall 148 with a manipulation port 304 through which a robotic arm 308 extends. A sealing element 312 creates a seal between the robotic arm 308 and the manipulation port 304. A robotic arm controller 316 may control the robotic arm 308 mechanically or electrically or both mechanically and electrically. The robotic arm 308 provides a mechanical force in the chamber 112. The robotic arm 308 may be telescopic and/or hinged and may rotate. The robotic arm 308 may also provide a clamp for grabbing and/or a lifter for lifting.

While this disclosure has been described in terms of several exemplary embodiments, there are alterations, modifications, permutations, and various substitute equivalents, which fall within the scope of this disclosure. It should also be noted that there are many alternative ways of implementing the methods and apparatuses of the present disclosure. It is therefore intended that the following appended claims be interpreted as including all such alterations, modifications, permutations, and various substitute equivalents as fall within the true spirit and scope of the present disclosure.

What is claimed is:

1. An apparatus for processing substrates, comprising:
a chamber, comprising:
a chamber top; and
a chamber bottom, wherein the chamber bottom is detachably connected to the chamber top;
at least one substrate support for supporting at least one substrate in the chamber;
a substrate port for moving a substrate into or out of the chamber;
a seal for creating a vacuum seal when the chamber top is on the chamber bottom; and
a manipulation system for manipulating an interior of the chamber when the chamber top is spaced apart from the chamber bottom, comprising:
a sealing wall for creating a seal between the chamber top and chamber bottom when the chamber top is spaced apart from the chamber bottom; and
a manipulation port in the sealing wall, wherein the manipulation port allows a mechanical force to be provided through the sealing wall inside the chamber.

2. The apparatus, as recited in claim 1, further comprising:
a gas inlet for providing gas into the chamber; and
a pressure system for sensing and maintaining a pressure in the chamber.

3. The apparatus, as recited in claim 1, wherein the manipulation port is at least one glove or a robotic arm port.

4. The apparatus, as recited in claim 1, wherein at least part of the sealing wall is transparent.

5. The apparatus, as recited in claim 1, further comprising a load lock chamber connected to the sealing wall, wherein the load lock chamber provides a port through the sealing wall.

6. The apparatus, as recited in claim 1, wherein the sealing wall further comprises an optical port for passing a light beam through the sealing wall.

7. The apparatus, as recited in claim 1, further comprising:
a top mounting system, wherein the top mounting system provides a seal between the sealing wall and the chamber top; and
a bottom mounting system, wherein the bottom mounting system provides a seal between the sealing wall and the chamber bottom.

8. The apparatus, as recited in claim 1, wherein the sealing wall is folded or bent when the chamber top is on the chamber bottom.

9. A vacuum chamber opening system for a chamber, wherein the chamber comprises a chamber top and a chamber bottom, wherein the vacuum chamber opening system seals the chamber as the chamber top is moved to be spaced apart from the chamber bottom, the vacuum chamber opening system, comprising:
a sealing wall for creating a seal between the chamber top and chamber bottom as the chamber top is moved to be spaced apart from the chamber bottom; and
a manipulation port in the sealing wall, wherein the manipulation port allows a mechanical force to be provided through the sealing wall inside the chamber when the chamber top is spaced apart from the chamber bottom.

10. The vacuum chamber opening system, as recited in claim 9, wherein the manipulation port is at least one glove or a robotic arm port.

11. The vacuum chamber opening system, as recited in claim 9, wherein at least part of the sealing wall is transparent.

12. The vacuum chamber opening system, as recited in claim 9, further comprising a load lock chamber connected to the sealing wall, wherein the load lock chamber provides a port through the sealing wall.

13. The vacuum chamber opening system, as recited in claim 9, wherein the sealing wall further comprises an optical port for passing a light beam through the sealing wall.

14. The vacuum chamber opening system, as recited in claim 9, further comprising:
a top mounting system, wherein the top mounting system provides a seal between the sealing wall and the chamber top; and
a bottom mounting system, wherein the bottom mounting system provides a seal between the sealing wall and the chamber bottom.

15. The vacuum chamber opening system, as recited in claim 14, wherein the sealing wall extends between the top mounting system and the bottom mounting system while the chamber top is on the chamber bottom and while the chamber top is spaced apart from the chamber bottom.

16. The vacuum chamber opening system, as recited in claim 14, wherein the top mounting system is removably mounted to the chamber top and wherein the bottom mounting system is removably mounted to the chamber bottom.

17. The vacuum chamber opening system, as recited in claim 9, wherein the sealing wall is folded or bent when the chamber top is on the chamber bottom.
